(19) United States
(12) Patent Application Publication
(10) Pub. No.: US 2025/0038048 A1
(43) Pub. Date: Jan. 30, 2025

(54) SUBSTRATE PROCESSING METHOD

(71) Applicant: ASM IP Holding B.V., Almere (NL)

(72) Inventors: Hyunchul Kim, Hwaseong-si (KR); SeungWoo Choi, Hwaseong-si (KR); WooSik Shin, Hwaseong-si (KR); KiHun Kim, Yongin-si (KR); YeaHyun Gu, Hwaseong-si (KR)

(21) Appl. No.: 18/912,027

(22) Filed: Oct. 10, 2024

Related U.S. Application Data
(63) Continuation of application No. 17/399,049, filed on Aug. 11, 2021, now Pat. No. 12,154,824.
(60) Provisional application No. 63/066,094, filed on Aug. 14, 2020.

(51) Int. Cl. H01L 21/768; H01J 37/32

(52) U.S. Cl. CPC H01L 21/76837; H01J 37/3244; H01L 21/76826; H01L 21/76834

(57) ABSTRACT

A substrate processing method capable of filling a gap structure without forming voids or seams in a gap while minimizing damage to the gap structure includes: forming a first thin film on a structure by performing a first cycle a plurality of times, the first cycle including supplying a first reaction gas onto the structure including a gap and purging a residue, forming a second thin film by changing a chemical composition of the first thin film, and forming a third thin film having the same component as that of the second thin film on the second thin film while filling the gap.

### CROSS-REFERENCE TO RELATED APPLICATIONS

This application is a continuation of, and claims priority to, U.S. patent application Ser. No. 17/399,049 filed Aug. 11, 2021 titled SUBSTRATE PROCESSING METHOD; which claims priority to U.S. Provisional Patent Application Ser. No. 63/066,094, filed on Aug. 14, 2020, the disclosures of which are incorporated herein in their entirety by reference.

### BACKGROUND

### 1. Field

One or more embodiments relate to a substrate processing method, and more particularly, to a substrate processing method of filling a gap formed in a structure on a substrate.

### 2. Description of the Related Art

In a metallization process for manufacturing a semiconductor integrated circuit, a patterning process and a gap filling process are performed to form a metal circuit on a metal film (a cut-mask process). When filling the inside of a gap formed in a structure by a process using plasma, a structure (e.g., a mask layer) around the gap may be damaged by radicals. Due to the features of atomic layer deposition to deposit thin films along the shape of the structure, voids are formed inside the gap as the gap is being filled. Due to the voids formed in the gap, a spacer mask layer to be protected in a subsequent dry etching process is damaged, which then causes defects in a subsequent metal film patterning process.

### SUMMARY

One or more embodiments include filling a gap without generating voids or seams while minimizing damage around the gap by radical ions in a gap filling process for a metal patterning process.

Additional aspects will be set forth in part in the description which follows and, in part, will be apparent from the description, or may be learned by practice of the presented embodiments of the disclosure.

According to one or more embodiments, a substrate processing method may include forming a first thin film on a structure by performing a first cycle a plurality of times, the first cycle including supplying a first reaction gas onto the structure including a gap and purging a residue, forming a second thin film by changing a chemical composition of the first thin film, and forming a third thin film having the same component as that of the second thin film on the second thin film while filling the gap.

According to an example of the substrate processing method, the substrate processing method may further include forming a passivation layer by supplying a thin-film formation inhibitor gas on the second thin film formed in the gap, prior to the forming of the third thin film.

According to another example of the substrate processing method, the thin film formation inhibitor gas may be supplied under a pulsed high-frequency power condition.

According to another example of the substrate processing method, the passivation layer may be formed on a second thin film in an upper portion of the gap.

According to another example of the substrate processing method, the passivation layer may inhibit the forming of the third thin film on the second thin film in the upper portion of the gap by removing a bonding site on the second thin film that binds to the first reaction gas.

According to another example of the substrate processing method, low-frequency power may be supplied during the forming of the third thin film.

According to another example of the substrate processing method, the third thin film may be formed from middle and lower portions of the gap and may fill the gap.

According to another example of the substrate processing method, during filling of the gap, a width of an inlet at the upper portion of the gap may be maintained to be greater than a lower width of the gap.

According to another example of the substrate processing method, the gap may be filled without generating voids in the gap.

According to another example of the substrate processing method, plasma may be applied for at least some period of the first cycle, and the first reaction gas may be dissociated by the plasma to adsorb the first thin film on the structure.

According to another example of the substrate processing method, during the first cycle, a second reaction gas that is not reactive with the first reaction gas may be supplied, and the first thin film may be densified by the second reaction gas.

According to another example of the substrate processing method, in order to minimize damage to the structure while forming the first thin film, the plasma may be supplied at pulsed low frequency and low power.

According to another example of the substrate processing method, the first reaction gas dissociated by the low frequency and low power may reach a lower portion of the gap.

According to one or more embodiments, a substrate processing method may include: a first operation of forming a first thin film by performing a first cycle a plurality of times, the first cycle including supplying a first reaction gas onto a structure including a gap, supplying a second reaction gas that is not reactive with the first reaction gas, applying plasma, and purging a residue; a second operation of forming a second thin film by changing a chemical composition of the first thin film by performing a second cycle a plurality of times, the second cycle including supplying a third reaction gas onto the first thin film, applying plasma to induce a reaction between the first thin film and the third reaction gas, and purging a residue; a third operation of forming a passivation layer on the second thin film inside the gap by performing a third cycle a plurality of times, the third cycle including supplying a thin film formation inhibitor gas on the second thin film inside the gap and applying plasma; and a fourth operation forming a third thin film on the second thin film by performing a fourth cycle a plurality of times, the fourth cycle including supplying the first reaction gas on the second thin film, supplying the third reaction gas, applying plasma, and purging a residue.

According to an example of the substrate processing method, the plasma in the third cycle may be applied via pulsed high-frequency power, and during the third cycle, the thin film formation inhibitor gas may be activated via high-frequency power to reach an upper portion of the gap, and the plasma in the fourth cycle may be applied via pulsed low-frequency power, and during the fourth cycle, the third reaction gas may be activated via the low-frequency power to reach a lower portion of the gap.

According to another example of the substrate processing method, the third operation and the fourth operation may be repeatedly performed until the gap is filled.

The amplitude of power supplied in the first operation of forming the first thin film on the structure and the second operation of changing the chemical composition of the first thin film to form the second thin film is less than the amplitude of power supplied in the third operation of forming the passivation layer on the second thin film and the fourth operation of forming the third thin film, so that damage to the structure may be minimized.

According to another example of the substrate processing method, a nitrogen gas is additionally supplied during at least one of the first operation, the second operation and the fourth operation, and the nitrogen gas may minimize damage to the structure by suppressing plasma generation during the forming of a thin film.

According to another example of the substrate processing method, the method may further include exposing the structure by performing etch-back on at least a portion of the structure, the second thin film and the third thin film. During the performing of the etch-back, the second thin film and the third thin film in the gap may not be removed.

According to another example of the substrate processing method, during the performing of the etch-back, the second thin film located in the gap may comprise a protective film protecting a lower structure of the gap.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view for explaining a metal patterning and gap filling process for a metallization process;

FIG. 2 is a cross-sectional view of a gap filled using the prior art and a void formed in the gap;

FIG. 3 is a view showing damage to a structure around a gap due to oxygen radicals when the gap is filled with an oxide film by using a plasma process during the gap filling process of FIG. 1 and problems associated therewith;

FIGS. 4 to 8 are cross-sectional views illustrating a method of manufacturing a semiconductor device according to embodiments;

FIGS. 9A to 9E are detailed views of a third thin film forming operation of FIG. 8;

FIG. 10 is a view illustrating a method capable of filling a gap without generating voids or seams while minimizing damage around the gap by radicals during a gap filling process for a metal patterning process;

FIG. 11 is a view illustrating a substrate processing method according to embodiments;

FIG. 12 is a view illustrating a substrate processing method according to embodiments;

FIG. 13 is a view illustrating a substrate processing method according to embodiments; and

FIG. 14 is a view illustrating a degree of loss of a lower SOH mask layer when performing a gap filling process under different conditions.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, one or more embodiments will be described more fully with reference to the accompanying drawings.

In this regard, the present embodiments may have different forms and should not be construed as being limited to the descriptions set forth herein. Rather, these embodiments are provided so that the present disclosure will be thorough and complete, and will fully convey the scope of the present disclosure to one of ordinary skill in the art.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

In the disclosure, “gas” may include evaporated solids and/or liquids and may include a single gas or a mixture of gases. In the disclosure, a process gas introduced into a reaction chamber through a shower head may include a precursor gas and an additive gas. The precursor gas and the additive gas may typically be introduced as a mixed gas or may be separately introduced into a reaction space. The precursor gas may be introduced together with a carrier gas such as an inert gas. The additive gas may include a dilution gas such as a reaction gas and an inert gas. The reaction gas and the dilution gas may be mixedly or separately introduced into the reaction space. The precursor may include two or more precursors, and the reaction gas may include two or more reaction gases. The precursor may be a gas that is chemisorbed onto a substrate and typically contains metalloid or metal elements constituting a main structure of a matrix of a dielectric film, and the reaction gas for deposition may be a gas that is reactive with the precursor chemisorbed onto the substrate when excited to fix an atomic layer or a monolayer on the substrate. The term “chemisorption” may refer to chemical saturation adsorption. A gas other than the process gas, that is, a gas introduced without passing through the shower head, may be used to seal the reaction space, and it may include a seal gas such as an inert gas. In some embodiments, the term “film” may refer to a layer that extends continuously in a direction perpendicular to a thickness direction without substantially having pinholes to cover an entire target or a relevant surface, or may refer to a layer that simply covers a target or a relevant surface. In some embodiments, the term “layer” may refer to a structure, or a synonym of a film, or a non-film structure having any thickness formed on a surface. The film or layer may include a discrete single film or layer or multiple films or layers having some characteristics, and the boundary between adjacent films or layers may be clear or unclear and may be set based on physical, chemical, and/or some other characteristics, formation processes or sequences, and/or functions or purposes of the adjacent films or layers.

In the disclosure, the expression “containing a Si—O bond” may be referred to as characterized by a Si—O bond or Si—O bonds having a main skeleton substantially constituted by the Si—O bond or Si—O bonds and/or having a substituent substantially constituted by the Si—O bond or Si—O bonds. A silicon oxide layer may be a dielectric layer containing a Si—O bond, and may include a silicon oxide layer (SiO) and a silicon oxynitride layer (SiON).

In the disclosure, the expression “same material” should be interpreted as meaning that main components (constituents) are the same. For example, when a first layer and a second layer are both silicon nitride layers and are formed of the same material, the first layer may be selected from the group consisting of Si₂N, SiN, Si₃N₄, and Si₂N₃ and the second layer may also be selected from the above group but a particular film quality thereof may be different from that of the first layer.

Additionally, in the disclosure, according as an operable range may be determined based on a regular job, any two variables may constitute an operable range of the variable and any indicated range may include or exclude end points. Additionally, the values of any indicated variables may refer to exact values or approximate values (regardless of whether they are indicated as “about”), may include equivalents, and may refer to an average value, a median value, a representative value, a majority value, or the like.

In the disclosure where conditions and/or structures are not specified, those of ordinary skill in the art may easily provide these conditions and/or structures as a matter of customary experiment in the light of the disclosure. In all described embodiments, any component used in an embodiment may be replaced with any equivalent component thereof, including those explicitly, necessarily, or essentially described herein, for intended purposes, and in addition, the disclosure may be similarly applied to devices and methods.

Hereinafter, embodiments of the disclosure will be described with reference to the accompanying drawings. In the drawings, variations from the illustrated shapes may be expected as a result of, for example, manufacturing techniques and/or tolerances. Thus, the embodiments of the disclosure should not be construed as being limited to the particular shapes of regions illustrated herein but may include deviations in shapes that result, for example, from manufacturing processes.

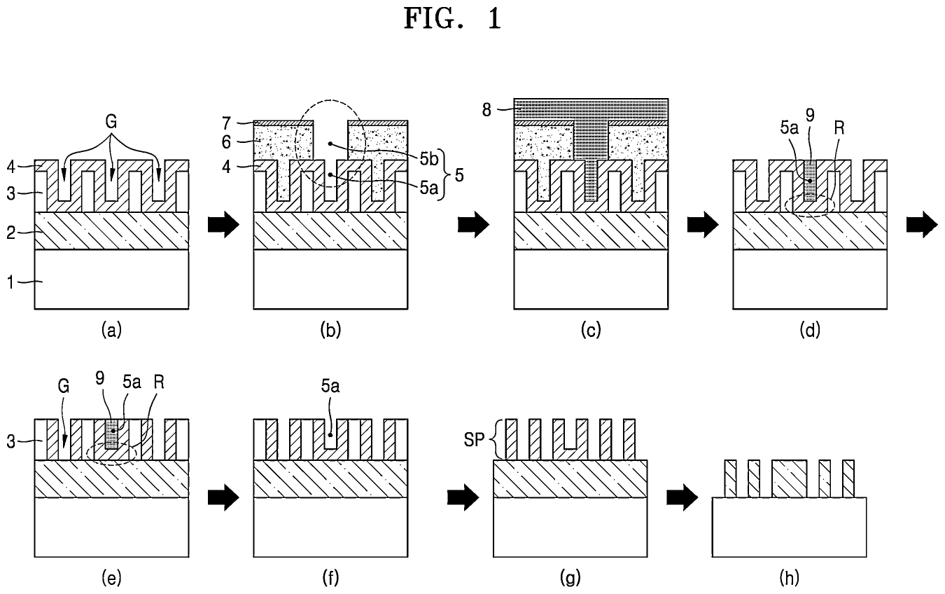

FIG. 1 is a cross-sectional view schematically showing a conventional patterning and gap filling process (a cut-mask process) for forming a metal circuit on a metal film during a metallization process for manufacturing a semiconductor integrated circuit (IC).

Referring to FIG. 1 (a), a metal film 2, which is a film to be etched, is formed on a substrate 1. The metal film 2 may be at least one of aluminum (Al), copper (Cu), tungsten (W), titanium nitride (TiN), or a conductive film. In some embodiments, an insulating film (not shown) may be added between the substrate 1 and the metal film 2, and the insulating film may block a reaction between the substrate 1 and the metal film 2 or prevent diffusion of metal ions from the metal film 2 to the substrate 1.

Thereafter, after forming a support (e.g., a mandrel) 3 for pattern formation on the metal film 2, a spacer mask film 4 is uniformly deposited thereon. The spacer mask film 4 may be an oxide film, for example, SiO₂ or TiO₂, or may be a mask layer used to pattern the metal film 2. In order to be uniformly deposited on a pattern structure of the support 3, the spacer mask film 4 is deposited by plasma atomic layer deposition. Accordingly, a gap G exists between supports 3.

Referring to FIG. 1 (b), a mask layer 6 is formed on the spacer mask film 4, and a hard mask film 7 is formed on the mask layer 6. The mask layer 6 may be a hard mask, in particular a hard mask containing carbon. For example, the mask layer 6 may be formed of a spin-on-hardmask (SOH) film or a carbon spin-on hardmask (C—SOH) film. The hard mask film 7 formed on the mask layer 6 may be a silicon oxynitride film (SiON).

Thereafter, a portion of the hard mask film 7 (a dotted circle portion in FIG. 1 (b)) is etched and removed through a lithography process. The mask layer 6 under the removed hard mask film 7 is removed through an ashing process using oxygen plasma. Because the mask layer 6 includes a carbon component, the mask layer 6 may be removed by reacting with the oxygen plasma. By removing a portion of the mask layer 6 (the dotted circle portion in FIG. 1 (b)), gaps 5a and 5b (i.e., 5) are generated between the spacer mask film 4 and the removed mask layer 6. Therefore, a structure including the gap 5 may be provided on the substrate 1.

Referring to FIG. 1 (c), an operation (hereinafter, operation (c)) of filling the gap 5 generated by removing the mask layer 6 with an oxide film 8 is performed. The oxide film 8 may be SiO₂. The oxide film 8 may be deposited by a process using plasma, for example, a PEALD or PECVD process to fill the gap 5. The gap 5 may be filled with the oxide film 8 by a deposition-etch-deposition method using a plasma atomic layer deposition method.

Referring to FIG. 1 (d), an operation in which the oxide film 8, the hard mask film 7, and the mask layer 6 formed on the spacer mask film 4 are etched back is performed (hereinafter, operation (d)). For example, films formed on the spacer mask film 4, that is, the oxide film 8, the hard mask film 7, and the mask layer 6 are removed by a chemical-mechanical polishing (CMP) method. At this time, an oxide film 9 located in the gap 5a between spacer mask films 4 is not removed. The oxide film 9 remaining between the spacer mask films 4 will be a protective film for protecting a portion R of the spacer mask film 4 in a subsequent etching operation (of FIG. 1 (e))

Referring to FIG. 1 (e), an operation of removing the spacer mask film 4 formed above the support 3 and the spacer mask film 4 formed on the bottom of the gap G between the supports 3 is performed by using dry etching (hereinafter, operation (e)). At this time, due to the oxide film 9 remaining between gaps 5a among gaps G, the portion R of the spacer mask film 4 therebelow is not removed, and may later be used as a mask for the metal film 2.

Referring to FIG. 1 (f), an operation of removing the oxide film 9 remaining in the gap 5a is performed using dry etching (hereinafter, operation (f)). For example, the oxide film 9 is dry etched using an etching gas that selectively reacts with the oxide film 9.

Referring to FIG. 1 (g), an operation of forming a spacer pattern SP for patterning the metal film 2 is performed (hereinafter, operation (g)). To this end, the support 3 is removed. Accordingly, the substrate 1 including the metal film 2, which is a film to be etched, and the spacer pattern SP formed on the metal film 2 may be provided.

Referring to FIG. 1 (h), an operation of dry etching the metal film 2, which is a film to be etched, is performed using the remaining portion of the spacer mask film 4 (i.e., the spacer pattern SP of FIG. 1 (g)) as a mask.

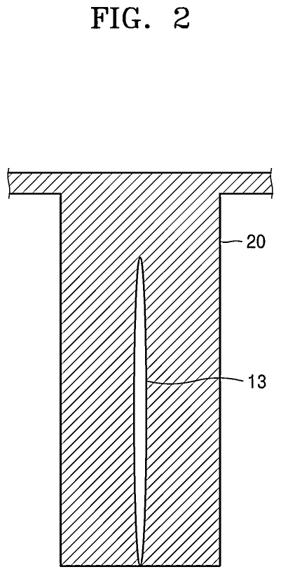

However, in general, when a gap is filled using conventional gap filling process technology, a problem occurs in that a void is formed inside the gap. FIG. 2 shows a problem of such prior art.

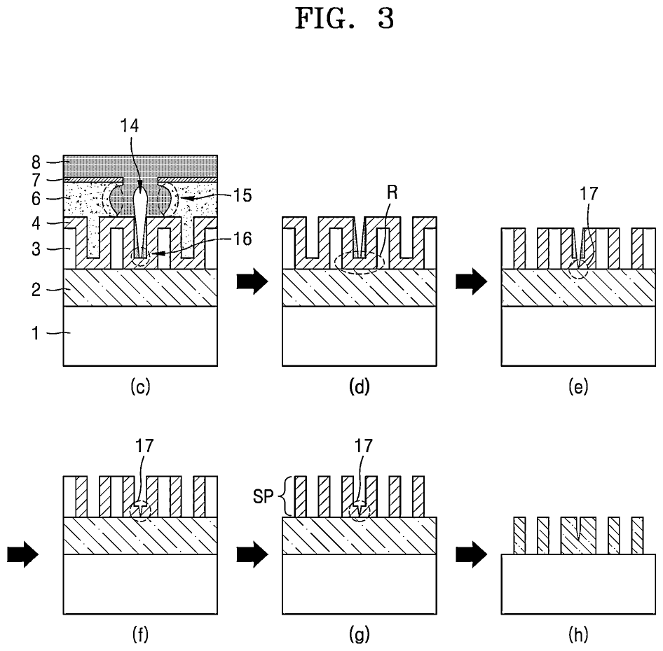

FIG. 2 shows a cross-sectional view of a gap 20 filled by a plasma process (e.g., PEALD) using an oxide. In general, when filling the gap 20 using an oxide, oxide walls are formed as the oxide is deposited on both side walls of the gap 20, and as the thickness increases, a width between the oxide walls decreases. Due to the decrease in a physical distance (width) between the oxide walls, it becomes increasingly difficult for a reaction gas to enter a lower portion of the gap, and deposition is concentrated in an upper portion of the gap, leaving voids or seams (not shown) between the oxide walls. These voids cause a defect in a metal film patterning process, as described later with reference to FIG. 3.

Furthermore, in operation (c) of FIG. 1, when filling the gaps 5a and 5b (i.e., 5) formed between the spacer mask films 4 and between removed mask layers 6 with the oxide film 8 using a plasma process, a portion of a structure may be damaged by activated oxygen radicals or the like. In more detail, when the inside of the gap 5 is filled with oxygen, oxygen radical active species are generated by plasma application, and a portion of the mask layer 6 (i.e., an SOH layer) and the spacer mask film 4 (i.e., a spacer oxide film) around the gap 5 may react with oxygen radicals and the film quality may be changed, or may be reduced to gas and volatilize, or may be physically damaged and the physical shape may be changed. Thereafter, voids are formed in a film filled between the damaged mask layer 6 and the spacer mask film 4. FIG. 3 shows a problem of such prior art.

FIG. 3 shows damage to a structure around a gap due to oxygen radicals when the gap is filled with an oxide film by using a PEALD process during the gap filling process of FIG. 1 and problems associated therewith.

As shown in FIG. 3 (c), when filling the inside of the gap 5 with the oxide film 8 using a plasma process in FIG. 1 (c), a structure around the gap 5, in particular a sidewall 15 of the mask layer 6, is damaged. As described with reference to FIG. 2, due to the characteristic of atomic layer deposition in which a thin film is uniformly deposited along a profile of a structure on which thin films are to be deposited, a void 14 is formed in the gap 5. Due to the void 14, the spacer mask film 4 at the bottom of the gap 5 is directly exposed as indicated by reference numeral 16, or the void 14 may penetrate the spacer mask film 4 and expand to the interior. In this case, when performing FIG. 1 (d), a portion of the spacer mask film R to be protected against an etching process is exposed (FIG. 3 (d)). Subsequently, when the etching process is performed on a portion of the spacer mask film by operation (e), a portion of the exposed spacer mask film R is etched (reference numeral 17 in FIG. 3 (e)), which then causes a defect in a patterning process of the metal film 2 (see FIG. 3 (g) and (h)).

To solve the problems of the prior art, the disclosure proposes a method of protecting structures around a gap from active radicals when filling the gap with an oxide and filling the gap without voids or seams being generated in the gap, in a patterning and gap filling process (a cut-mask process) for a metal patterning process.

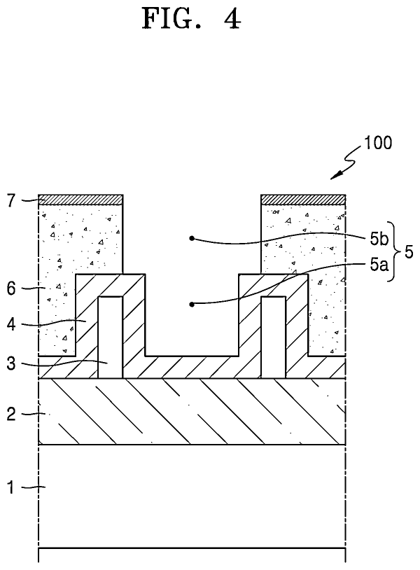

FIGS. 4 to 8 are cross-sectional views illustrating a method of manufacturing a semiconductor device according to embodiments.

Referring to FIG. 4, the substrate 1 including a gap structure 100 is mounted on a substrate support (not shown). The gap structure 100 of FIG. 4 is the same as the gap structure of FIG. 1 (b), and specifically includes the metal film 2, the support 3, the spacer mask film 4, the mask layer 6, the hard mask film 7, and the gap 5 formed between the spacer mask films 4 and between the mask layers 6. The substrate support may be a heating block.

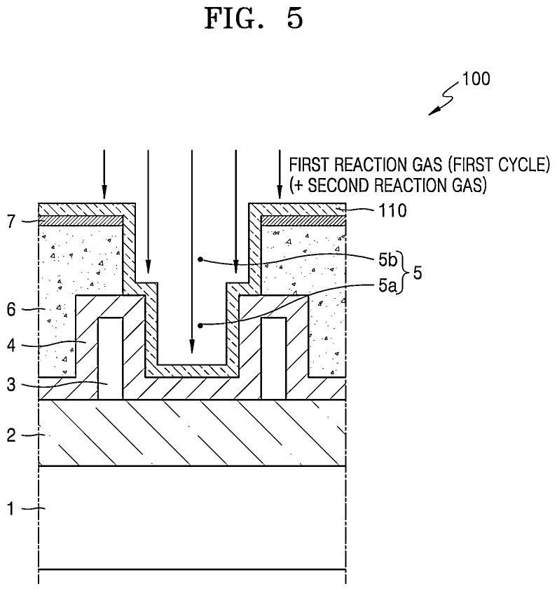

Referring to FIG. 5, a first thin film 110 is formed on the gap structure 100. The first thin film 110 may be formed on the gap structure 100 by performing a first cycle including supplying a first reaction gas onto the gap structure 100 including the gap 5 and purging the residue a plurality of times. The first cycle may be repeated one or more times, and a thickness of the first thin film 110 may increase as the first cycle is repeated. As described below, the first thin film 110 may be a protective layer that prevents a lower film (e.g., the mask layer 6 and the spacer mask film 4) from being damaged by plasma radicals.

The first reaction gas used to form the first thin film 110 may include a silicon-containing source gas. In an example, a silicon-containing source gas is supplied onto the gap structure 100 so that a silicon-containing material layer adsorbed (e.g., chemically adsorbed) on the gap structure 100 may be formed as the first thin film 110. For example, the first reaction gas may be an aminosilane-based silicon-containing source gas containing a methyl group (—CₙH₂ₙ₊₁) or an ethyl group (—CₙH₂ₙ₊₂). That is, the first reaction gas may include a silicon source containing a carbon element. Accordingly, the material layer 110 formed by the first reaction gas may include a silicon element and a carbon element.

In some examples, the first thin film 110 may include a mixture of at least one of elements constituting the first reaction gas (e.g., silicon (Si), nitrogen (N), hydrogen (H), carbon (C), an alkyl group (—CₙH₂ₙ₊₁), and ligand fragments). The first thin film 110 may be formed by adsorbing the mixture on the gap structure 100.

In some embodiments, plasma may be applied for at least some period of a first cycle to form the first thin film 110. The first reaction gas may be dissociated by the plasma, and the first thin film 110 may be adsorbed on the gap structure 100. For example, the first thin film 110 may be formed by a PEALD deposition method.

In some embodiments, in order to promote the dissociation of the first reaction gas and/or densify the first thin film 110, a second reaction gas may be supplied during the first cycle. During the first cycle, a first reaction gas and a second reaction gas may be alternately and sequentially supplied to the gap structure 100. For example, during the application of the above-described plasma, a second reaction gas that is not reactive with the first reaction gas may be supplied. For example, the second reaction gas may include at least one inert element such as argon (Ar) and helium (He). The second reaction gas may be activated by plasma, but may not chemically react with the thermally and chemically adsorbed first thin film 110. The thermally and chemically adsorbed first thin film 110 may be decomposed and densified by an ion bombardment effect of the activated second reaction gas.

To protect a lower film (i.e., the hard mask film 7, the mask layer 6, and the spacer mask film 4) from radicals activated by plasma during the forming of the first thin film 110, plasma for activating the first reaction gas and/or the second reaction gas may be supplied at low power. In addition, the plasma is supplied as pulsed plasma to further reduce damage to the lower film. When supplying a power by the pulsed plasma, the power may be supplied in the form of a pulse with a duty ratio of about 30% to about 70%. Accordingly, plasma for activating the first reaction gas and/or the second reaction gas is supplied at pulsed low power, thereby minimizing damage to the lower film. Further, in order to form the first thin film 110 up to a lower portion of the gap 5a, plasma may be applied via low-frequency power. The ion density is low under low-frequency power, but a mean free path (MFP) of ions is long instead, so that the first reaction gas and/or the second reaction gas dissociated by the low-frequency power may reach a lower portion of the gap 5a. Thus, the first thin film 110 may be formed up to the lower portion of the gap 5a. Therefore, when forming the first thin film 110, it is preferable that plasma is supplied at pulsed low frequency and low power.

In some embodiments, while the first thin film 110 is formed, a portion of the first thin film 110 may react with a lower gap structure 100. For example, the first thin film 110 may include a chemical bond formed by one element of a mixture constituting the first thin film 110 reacting with at least one of elements constituting the gap structure 100.

As a more specific example, the first reaction gas may include a silicon element, and thus the mixture of the first thin film 110 formed by the first reaction gas may include a silicon element. Meanwhile, the spacer mask film 4 and/or the mask layer 6 under the first thin film 110 may include an oxygen element. In this case, a portion of the first thin film 110 may contain a Si—O bond. In particular, the Si—O bond may be formed in a portion of the first thin film 110 adjacent to the spacer mask film 4 and/or the mask layer 6.

The Si—O bond is not formed in a process of oxidizing the spacer mask film 4 and/or the mask layer 6, but is formed by bonding some of oxygen elements in the spacer mask film 4 and/or the mask layer 6 near the gap 5, for example, some of oxygen elements of an O₂-terminated site or dangling bonded oxygen elements with a silicon component of the first thin film 110. Therefore, the first thin film 110 having the Si—O bond may be formed without damage to the spacer mask film 4 and/or the mask layer 6.

Furthermore, the Si—O bond may be a protective film to prevent damage to the spacer mask film 4 and/or the mask layer 6 in a process of changing the first thin film 110 to the second thin film 120 to be subsequently performed. In other words, a silicon oxide layer formed on a portion of the first thin film 110 is formed without damaging the spacer mask film 4 and/or the mask layer 6, and the silicon oxide layer may protect the spacer mask film 4 and/or the mask layer 6 during the subsequent process.

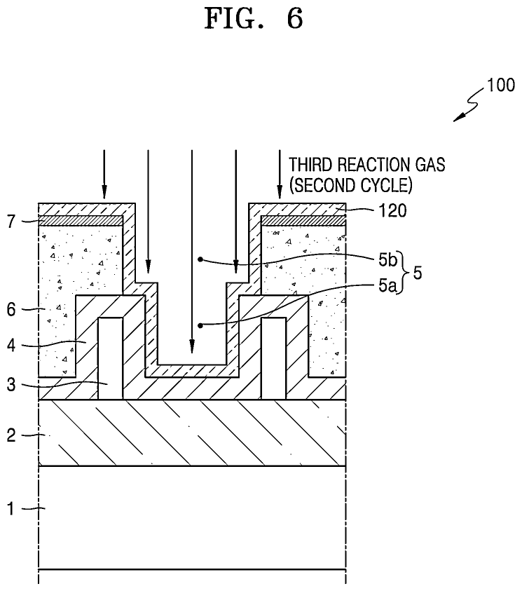

Referring to FIG. 6, after the forming of the first thin film 110, the second thin film 120 is formed by changing a chemical composition of the first thin film 110. For example, a third reaction gas that is reactive with the first thin film 110 may be supplied. The first thin film 110 may be changed to the second thin film 120 due to the supply of the third reaction gas.

During the forming of the second thin film 120, a second cycle may be performed a plurality of times. The second cycle may include supplying the third reaction gas onto the first thin film 110 and purging the residue. In order to promote a reaction between the third reaction gas and the first thin film 110, plasma may be applied. That is, during the second cycle, inducing the reaction between the first thin film 110 and the third reaction gas by applying plasma may further be performed. At this time, the third reaction gas is activated by plasma, and may chemically react with the first thin film 110.

In an example, the third reaction gas may include oxygen. In this case, during the inducing of the reaction between the above-described first thin film 110 and the third reaction gas, the first thin film 110 may be oxidized to form the second thin film 120. For example, when a silicon-containing source gas is supplied to form the first thin film 110, a chemical component of the first thin film 110 may be changed (e.g., oxidized) by supplying a reaction gas (e.g., an oxygen gas) that is reactive with the silicon-containing source gas. In this case, the first thin film 110 may be converted to the second thin film 120 of silicon oxide (SiO₂).

The third reaction gas may have reactivity with the first patterned structure 120. For example, as described above, the third reaction gas may include oxygen, and thus may oxidize the SOH layer 6.

Therefore, it is necessary to prevent oxidation of the SOH layer 6 under the first thin film 110 during the forming of the second thin film 120 by supplying the third reaction gas. That is, it is necessary to protect the SOH layer 6 from the third reaction gas activated by plasma during the forming of the second thin film 120. To this end, the plasma for activating the third reaction gas may be supplied at low power. In addition, the plasma may be supplied as pulsed plasma to further reduce damage to a lower film (i.e., the mask layer 6). When supplying a power in the form of a pulse, the power may be supplied in the form of a pulse with a duty ratio of about 30% to about 70%. Accordingly, the plasma for activating the third reaction gas is supplied at pulsed low power, thereby minimizing damage (i.e., oxidation) to the mask layer 6. Further, in order to convert the first thin film 110 in the lower portion of the gap 5a to the second thin film 120, plasma may be applied via low-frequency power. The third reaction gas dissociated by the low-frequency power may reach the lower portion of the gap 5a.

On the other hand, the number of repetitions of the second cycle may be adjusted to prevent damage to the mask layer 6. For example, when a second cycle in which an oxygen gas is supplied and plasma is applied to oxidize the first thin film 110 of a certain thickness is excessively repeated, excessive repetition of the second cycle may cause oxidation of the mask layer 6. Therefore, the second cycle may be repeated within a range in which oxidation of the mask layer 6 does not occur. For example, the second cycle may be repeated 1 to 50 times, and preferably, the second cycle may be repeated 1 to 20 times (see Table 1 below).

A residue that is purged during the second cycle performed to form the second thin film 120 may include a constituent element of the first thin film 110. For example, the first thin film 110 may include Si source molecular fragments (e.g., Si—N—, Si—C—, Si—H—, and Si—CₙH₂ₙ₊₁) in which a bonding structure between elements is destroyed or individual elements (e.g., Si, C, N, and H). In this case, a residue including at least one of CH₄, C₂H₅, N(C₂H₅)₂, CO₂, NO, H₂O, and H₂ may be purged during the second cycle.

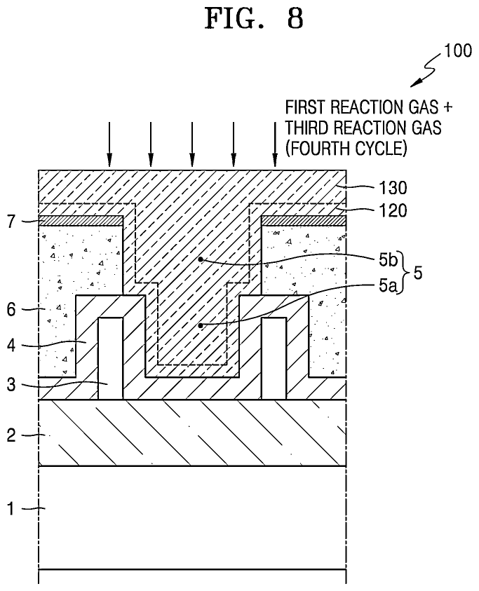

The second thin film 120 formed as described above may be a protective film for protecting the spacer mask film 4 under the gap 5a when subsequently exposing the gap structure 100 by performing etch-back on at least a portion of the gap structure 100, the second thin film 120, and a third thin film 130 (of FIG. 8).

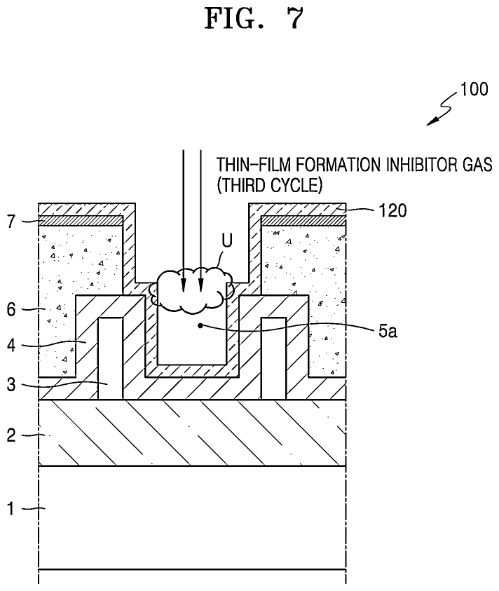

Referring to FIG. 7, before filling the gap 5 with the third thin film 130 (of FIG. 8) having the same component as that of the second thin film 120, a passivation layer may be formed by supplying a thin-film formation inhibitor gas on the second thin film 120 formed in the gap 5. A third cycle including locally supplying a thin film formation inhibitor gas on the second thin film 120 inside the gap 5a and purging the residue is performed a plurality of times, so that a passivation layer may be formed on the second thin film 120 inside the gap 5a.

The passivation layer may be formed on the second thin film 120 to remove bonding sites on the second thin film that bind to the first reaction gas and/or the third reaction gas. For example, hydrogen-terminated sites on the second thin film capable of binding to the first reaction gas may be removed. Therefore, when filling the gap 5 using the first reaction gas thereafter, the second thin film 120 on which the passivation layer is formed will not bind to the first reaction gas, and the first reaction gas will not be deposited thereon.

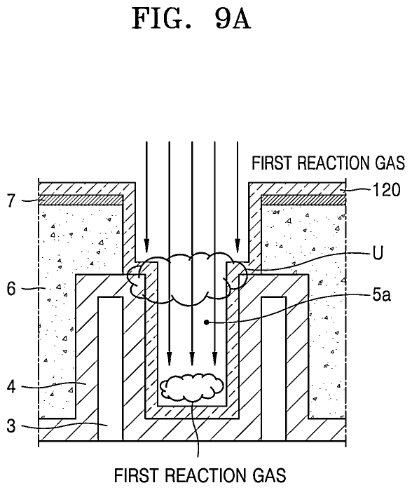

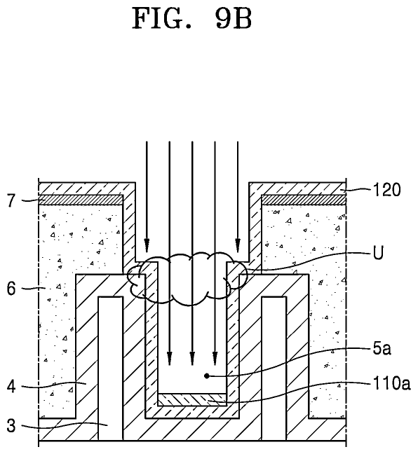

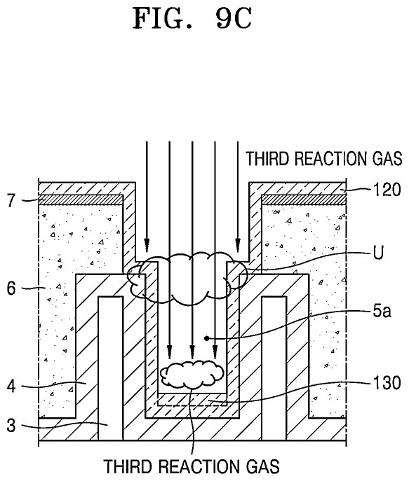

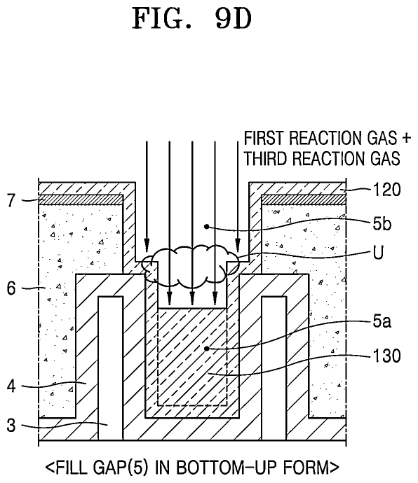

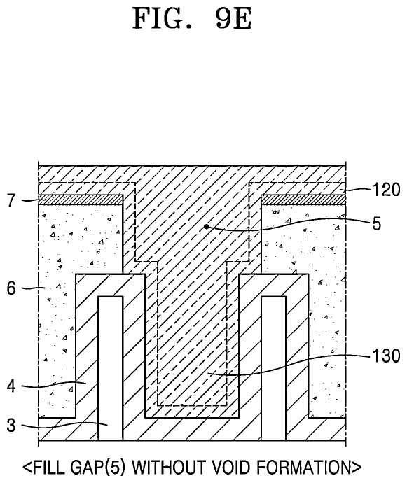

This passivation layer may be formed on the second thin film 120 of an upper area U of the gap 5a, and it is preferable to remove their bonding sites. Because, when the gap 5 is filled as described above with reference to FIG. 2, the filling gas (in this case, the first reaction gas and the third reaction gas) may be concentrated on an upper portion of the gap 5. This is because when a passivation layer is formed in the upper portion of the gap 5, this upper concentration phenomenon may be removed. In other words, the passivation layer formed on the upper area U of the gap 5a may prevent a phenomenon in which the first reaction gas and the third reaction gas are first deposited on the upper portion than the lower portion of the gap 5 to close the gap 5 (see FIGS. 9A to 9C).

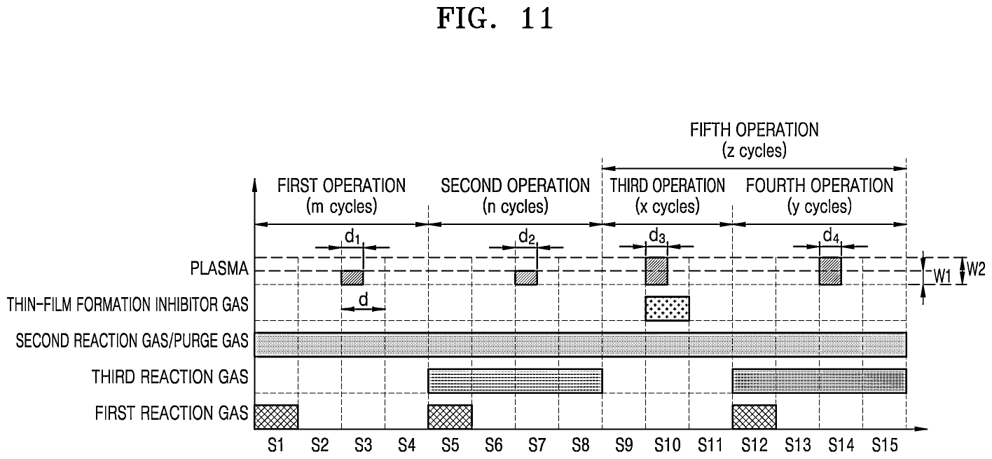

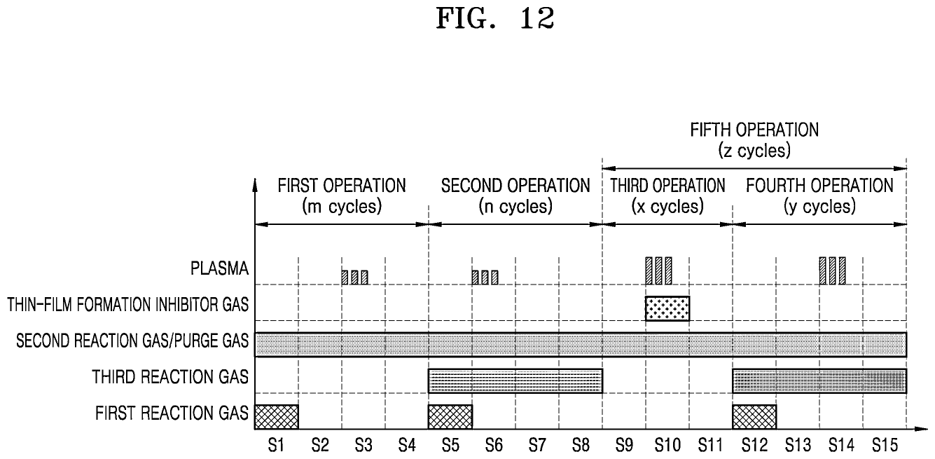

In some embodiments, plasma may be applied for at least some period of the third cycle to activate the thin-film formation inhibitor gas (see FIGS. 11 and 12). In particular, the plasma may be applied via high-frequency power to form a passivation layer on the upper area U of the gap 5a. At this time, the thin film formation inhibitor gas may be supplied under high-frequency power to reach the upper area U of the gap 5a. Because the ion density of the thin film formation inhibitor gas activated under the high-frequency power increases and an MFP of ions becomes short, a reaching area of the thin film formation inhibitor gas may be limited to the upper area U of the gap 5a, and it is possible to minimize the thin film formation inhibitor gas from reaching the lower portion of the gap 5a. In addition, the plasma is supplied in the form of a pulse to lower damage to a lower film. When supplying a power in the form of a pulse, the power may be supplied in the form of a pulse with a duty ratio of about 30% to about 70%. Therefore, when forming the passivation layer in the upper area U of the gap 5a, it is preferable that the thin film formation inhibitor gas is supplied under a pulsed high-frequency power condition. In an example, the thin film formation inhibitor gas may include nitrogen. In this case, nitrogen gas may be activated via plasma during the above-described plasma application.

Referring to FIG. 8, the third thin film 130 is formed on the second thin film 120 while filling the gap 5. In order to form the third thin film 130, an atomic layer deposition (ALD) process may be used. For example, the third thin film 130 may be formed while filling the gap 5 by repeating a fourth cycle including a source supply operation, a source purge operation, a reactant supply operation, and a reactant purge operation a plurality of times. In another example, a chemical vapor deposition (CVD) process using the first reaction gas and a third reaction gas may be used to form the third thin film 130.

In some embodiments using the ALD process, the first reaction gas described above (e.g., a silicon-containing source gas) may be used as the source, and the third reaction gas (e.g., a reaction gas that is reactive with a source gas such as an oxygen gas) may be used as the reactant. Therefore, the third thin film 130 may include the same component as that of the second thin film 120. For example, the second thin film 120 and the third thin film 130 may be silicon oxide (SiO₂) thin films.

For example, the fourth cycle may include supplying the first reaction gas and supplying the third reaction gas on the second thin film 120 (see FIGS. 11 and 12). When the ALD process is used to form the third thin film 130, the fourth cycle may further include purging a residue after the supplying of the first reaction gas and purging a residue after the supplying of the third reaction gas.

Therefore, similar to the operations described with reference to FIGS. 5 and 6, the first reaction gas may be deposited on the second thin film 120 to form the first thin film, and the first thin film may be changed to the third thin film 130 due to the supply of the third reaction gas. As described above, the third thin film 130 may include the same component as that of the second thin film 120.

In order to promote a reaction between the third reaction gas and the first thin film, plasma may be applied. That is, for at least some period of the fourth cycle, inducing the reaction between the first thin film and the third reaction gas by applying plasma may further be performed. At this time, the third reaction gas is activated by plasma, and may chemically react with the first thin film 110. Further, in order to form the third thin film 130 up to the lower portion of the gap 5a, plasma may be applied via low-frequency power. The ion density is low under low-frequency power, but an MFP of ions is long instead, so that the first reaction gas and/or the third reaction gas dissociated by the low-frequency power may reach the lower portion of the gap 5a. Thus, the third thin film 130 may be formed up to the lower portion of the gap 5a. In an example, the third reaction gas during the fourth cycle may be activated at a relatively lower frequency than that of a thin film formation inhibitor gas during the third cycle. In addition, the plasma is supplied in the form of a pulse to lower damage to a lower film. When supplying a power in the form of a pulse, the power may be supplied in the form of a pulse with a duty ratio of about 30% to about 70%. Therefore, when forming the third thin film 130, it is preferable that the first reaction gas and/or the third reaction gas are supplied under pulsed low-frequency power.

In an example, the third reaction gas may include oxygen. In this case, during the inducing of the reaction between the above-described first thin film and the third reaction gas, the first thin film may be oxidized to form the third thin film. For example, when a silicon-containing source gas is supplied to form the first thin film, a chemical component of the first thin film may be changed (e.g., oxidized) by supplying a reaction gas (e.g., an oxygen gas) that is reactive with the silicon-containing source gas.

FIGS. 9A to 9E are detailed views of a third thin film forming operation of FIG. 8.

Referring to FIG. 9A, a first reaction gas is supplied. At this time, a passivation layer is formed on the second thin film 120 of the upper area U of the gap 5a by the third cycle of FIG. 7. Such a passivation layer may inhibit forming of a first thin film or a third thin film on the second thin film 120 of the upper area U of the gap 5a by removing bonding sites on the second thin film binding to the first reaction gas. As described above with reference to FIG. 2, when filling the gap 5a, the filling gas (in this case, the first reaction gas) may be concentrated in an upper portion of the gap 5a. Because the passivation layer removes the bonding sites on the second thin film 120, the first reaction gas is not deposited on the second thin film 120 of the upper portion of the gap 5a. In addition, as described above, the first reaction gas may be supplied under low-frequency power to reach the lower portion of the gap 5a. Accordingly, as illustrated in FIG. 9B, a first thin film 110a may be deposited on the second thin film 120 at the lower portion of the gap 5a.

Referring to FIG. 9C, a third reaction gas is supplied. Likewise, the third reaction gas may be supplied under low-frequency power to reach the lower portion of the gap 5a. Accordingly, the third reaction gas and the first thin film 110a may react chemically to change the first thin film 110a to the third thin film 130. As described above, the third thin film 130 may include the same component as that of the second thin film 120. Because the first thin film 110a is not deposited on the upper area U of the gap 5a, the third thin film 130 is also not formed thereon.

By alternately and sequentially supplying the first reaction gas and the third reaction gas, the gap 5a may be filled during the forming of the third thin film 130. At this time, as shown in FIGS. 9C to 9E, the third thin film 130 may be formed in a bottom-up form from middle and lower portions of the gap 5a to the upper portion of the gap 5a to fill the gap 5a.

As such, the passivation layer formed on the upper area U of the gap 5a may prevent a phenomenon in which the first reaction gas and the third reaction gas are first deposited on the upper portion than the lower portion of the gap 5a to close the gap 5a. That is, a width of an inlet of the upper area U of the gap 5a may be maintained to be greater than a lower width of the gap 5a due to the passivation layer, thereby preventing the gap 5a from closing. Therefore, according to this method, the gap 5a may be filled without generating voids or seams. Subsequently, operations (d) to (h) of FIG. 1 may be performed on the structure in which the gap is filled by the operations of FIG. 8. In particular, operation (d) may be performed to expose the gap structure 100 by performing etch-back on at least a portion of the gap structure 100, the second thin film 120, and the third thin film 130. During the performing of the etch-back, the second thin film 120 and the third thin film 130 in the gap 5a remain without being removed, and may serve as a protective film protecting a lower structure of the gap (here, the spacer mask film 4 under the lower portion of the gap 5a).

FIGS. 7 to 9 illustrate an embodiment in which the third thin film 130 is formed after forming the passivation layer, but the disclosure is not limited thereto. In some embodiments, a group cycle that repeats the third and fourth cycles at least once may be configured to repeat this until the gap 5 is filled. In some embodiments, the third and fourth cycles may be repeated at a constant rate. For example, a group cycle or a super cycle in which the third cycle is repeated once and the fourth cycle is repeated five times may be configured and repeated. As another example, the third cycle and the fourth cycle may be repeated at a ratio of 1:10 or 1:20. Accordingly, it is possible to fill the gap while repeatedly forming the passivation layer and the third thin film. As the passivation layer is periodically generated, a phenomenon that the first thin film 110 is formed on the upper area of gap 5a may be more effectively prevented.

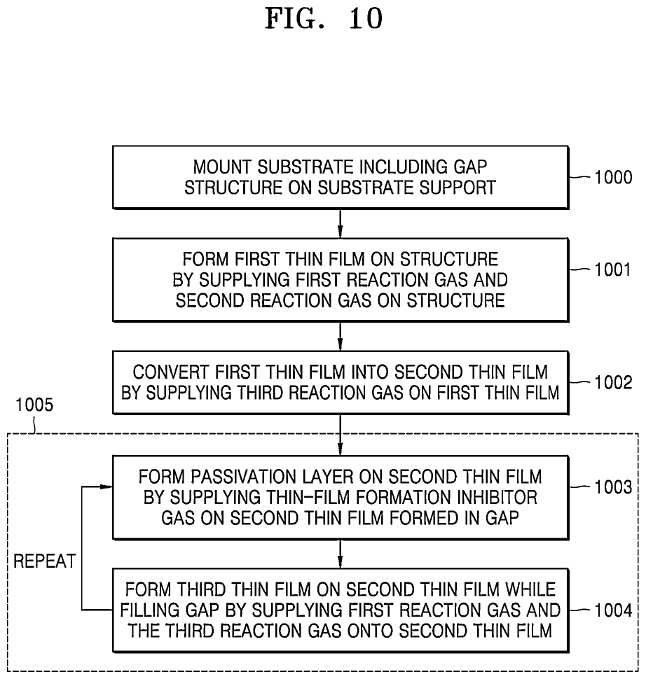

FIG. 10 is a view illustrating a substrate processing method according to embodiments. In particular, FIG. 10 shows a method of filling a gap of a gap structure without generating voids or seams while minimizing damage to structures around the gap by radicals during a gap filling process for a metal patterning process. Operations of FIG. 12 may be described as follows.

Substrate preparation operation 1000: A substrate including a structure including a gap is mounted on a substrate support. The structure may include a gap, a pattern structure, and a mask film. For example, a material of the mask film may be an SOH. The substrate support may be a heating block.

First operation 1001: A first thin film is formed by supplying a first reaction gas and a second reaction gas on the structure including the gap. The second reaction gas may be a gas that is not reactive with the first reaction gas and the structure. In an embodiment, the second reaction gas may be an inert gas activated by low frequency and low power applied to a reaction space, for example, an Ar radical. The first reaction gas may be a material including a thin film constituent material and may be supplied to the substrate by a carrier gas. In an embodiment, the first reaction gas may be a source material containing a Si element. The first thin film may be formed while consecutively supplying the first reaction gas and the second reaction gas, and is repeated at least once. In the first operation, because the second reaction gas has no chemical reactivity with the first reaction gas, the first thin film to be deposited may include a first reaction gas dissociated by applied low-frequency power, such as a constituent material of the source material, and at the same time is densified on the substrate by the second reaction gas. For example, when the first reaction gas is a Si source material containing carbon, nitrogen, and hydrogen components, the first thin film may be a Si source molecular fragment in which a bonding structure between constituent elements is destroyed, or individual Si, carbon, nitrogen, and hydrogen elements, random mixtures of the corresponding elements, or a mixture of weak bonds consisting of physical bonding weaker than chemical bonding.

Second operation 1002: The first thin film is converted into a second thin film by supplying a third reaction gas on the first thin film formed in the first operation 1001. The third reaction gas is a material having chemical reactivity with the first reaction gas, and may be, for example, an activated gas containing oxygen. In more detail, the first thin film is converted to the second thin film by a chemical reaction between the first thin film formed in the first operation 1001 and the third reaction gas supplied in the second operation 1002. In some embodiments, the conversion may be a process of oxidizing the first thin film. For example, when the first thin film is a mixture containing a Si element and the third reaction gas is an oxygen radical, the second thin film may be a silicon oxide (SiO₂) thin film. In the second operation 1002, reaction by-products between the first thin film and the third reaction gas may be removed and exhausted out of a reactor. This operation may be repeated at least once.

Third operation 1003: A passivation layer is formed on the second thin film by supplying a thin-film formation inhibitor gas on the second thin film formed in the gap. The thin film formation inhibitor gas may be supplied under high-frequency power to reach an upper portion of the gap. The passivation layer is particularly formed on the second thin film in the upper portion of the gap, so as to remove bonding sites on the second thin film capable of bonding to the first reaction gas. The thin film formation inhibitor gas may be a nitrogen-containing gas, more preferably a nitrogen gas. The thin film formation inhibitor gas may be activated by plasma. This operation may be repeated at least once.

Fourth operation 1004: A third thin film may be formed on the second thin film while filling the gap. The third thin film may have the same film quality as the second thin film, and may be, for example, a SiO₂ thin film. The first reaction gas and the third reaction gas may be alternately and sequentially supplied onto the second thin film to form the third thin film and fill the gap. In some embodiments, the third thin film may be a SiO₂ film formed by a PEALD method. Because a passivation layer (i.e., a thin film formation inhibiting layer) is formed in the upper portion of the gap in the third operation 1003, in fourth operation 1004, the first reaction gas and the third reaction gas fill the gap during the forming of the third thin film from middle and lower portions of the gap. Also, during the fourth operation 1004, the first reaction gas and the third reaction gas are activated via low-frequency power and may easily reach the lower area of the gap. This operation may be repeated at least once.

Fifth operation 1005: The third operation 1003 and the fourth operation 1004 may be repeated at least once at a constant rate. For example, a group cycle or a super cycle in which the third cycle is repeated once and the fourth cycle is repeated five times may be configured and repeated. As another example, the third cycle and the fourth cycle may be repeated at a ratio of 1:10 or 1:20. Accordingly, it is possible to fill the gap while repeatedly forming the passivation layer and the third thin film. By periodically generating a passivation layer, a width of an inlet of the upper area U of the gap may be maintained to be greater than a lower width of the gap. Accordingly, the gap may be filled without voids or seams being generated in the gap structure.

FIG. 11 is a view illustrating a substrate processing method according to embodiments. The substrate processing method according to the embodiments may be a variation of the substrate processing method according to the above-described embodiments. Hereinafter, repeated descriptions of the embodiments will not be given herein.

Referring to FIG. 11, a substrate is processed using a first reaction gas, a second reaction gas, a third reaction gas, and a thin-film formation inhibitor gas. Hereinafter, it will be described on the premise that the first reaction gas contains a Si source gas, the second reaction gas contains an Ar gas, the third reaction gas contains an oxygen-containing gas, more specifically N₂O, and the thin film formation inhibitor gas contains a nitrogen gas.

First operation: First, a first thin film is formed. In the first operation, the first thin film is formed on a gap structure while the Si source gas and the Ar gas are alternately supplied. When the Ar gas is supplied, low-frequency power is supplied to a reaction space, whereby the Si source gas and the Ar gas are dissociated. Because the Si source gas and Ar plasma have no chemical reactivity, the first thin film includes a Si source material dissociated by the applied low frequency and low power. When the Si source gas is an aminosilane gas composed of nitrogen and an alkyl group (CₙH₂ₙ₊₁), for example, diisopropylaminosilane (DIPAS), the Si source gas may be Si source molecular fragments in which a bonding structure between constituent elements is destroyed or individual Si, carbon, nitrogen, and hydrogen elements, or a mixture of the corresponding elements. The Si source gas may be a mixture of weak bonds consisting of physical bonding weaker than chemical bonding. However, the very first layer of the Si source gas adsorbed on the gap structure may react with an H-terminate site on a surface of a lower gap structure to form a —Si—O-chemical bond.

In the first operation, the first thin film may be more densified on the gap structure due to an ion bombardment effect of the Ar radical. By activating an Ar gas other than an oxygen gas to form the first thin film on the gap structure, it has a technical effect of preventing deformation of a lower structure. In the first operation, plasma is supplied at a duty ratio of about 50% (i.e., d1/d=0.5). In some embodiments, to prevent damage to the lower structure during the forming of the first thin film, plasma may be supplied in the form of a pulse as shown in FIG. 12.

The Ar gas is a purge gas as well as a second gas, and reaction by-products are purged and removed from the reaction space by an Ar purge gas.

The first operation is repeated several times (m times) to form the first thin film having a certain thickness.

Second operation: After the first operation, oxygen treatment and oxidation is performed. In the second operation, while supplying an oxygen-containing gas, the first thin film is converted into a second thin film, that is, a SiO₂ film. When an oxygen-containing gas, a third reaction gas, is supplied, low-frequency power is applied to the reaction space to form an oxygen radical, and the oxygen radical reacts chemically with Si-bonded molecular fragments in the first thin film to form a SiO₂ thin film. For example, molecular fragments containing Si elements, such as Si—N—, Si—C—, Si—H—, and Si—CₙH₂ₙ₊₁, and oxygen radicals may react chemically with each other to form the SiO₂ film. As an example of by-products of the chemical reaction, there may be various combinations of by-products such as CH₄, C₂H₅, N(C₂H₅)₂, CO₂, NO, H₂O, H₂, etc., which are purged and removed from the reaction space by the Ar purge gas.

In the second operation, plasma is supplied at a duty ratio of about 50% (i.e., d2/d=0.5). In some embodiments, to prevent damage to the lower structure during the forming of the second thin film, plasma may be supplied in the form of a pulse as shown in FIG. 12.

The second operation is repeated several times (n times) to form a second thin film.

Third operation: After the second operation, a passivation layer is formed. In the third operation, while supplying a nitrogen gas as a thin film formation inhibitor gas, H-terminated sites, which are bonding sites on the second thin film, are removed to inhibit forming of a third thin film in the fourth operation.

When nitrogen gas, which is a thin film formation inhibitor gas, is supplied, high-frequency power is applied to the reaction space to generate nitrogen radicals, and because an MFP of nitrogen radicals activated via high-frequency power is short, the reaching area is limited to an upper portion of the gap. Accordingly, the thin film formation inhibitor gas may remove the H-terminated sites on the second thin film located in the upper portion of the gap.

In the third operation, plasma is supplied at a duty ratio of about 50% (i.e., d3/d=0.5). In some embodiments, to prevent damage to the lower structure during the forming of the passivation layer, plasma may be supplied in the form of a pulse as shown in FIG. 12.

The third operation is repeated several times (x times) to form the passivation layer.

Fourth operation: A third thin film is formed to fill the gap. In the fourth operation, the gap is filled during the forming of the third thin film on the second thin film. In the fourth operation, a third SiO₂ thin film is deposited on the second thin film while alternately and consecutively supplying the Si source gas, which is the first reaction gas, and the third reaction gas. It is preferable that the second thin film and the third thin film have the same film quality, and problems such as delamination of the second thin film and the third thin film that may occur in a subsequent heat treatment process may be prevented. The Si source gas reacts with an H-terminated site on a surface of the lower structure to form a —Si—O-chemical bond and deposit the same. Because the H-terminated site on the second thin film located at the top of the gap is removed in the third operation, the Si source gas supplied during the fourth operation is deposited from the middle and lower portions of the gap. When an oxygen-containing gas, which is the third reaction gas, is supplied, low-frequency power is applied to the reaction space to form oxygen radicals, and the oxygen radicals activated via low-frequency power may reach the middle and lower portions of the gap to form a third thin film there.

In the fourth operation, plasma is supplied at a duty ratio of about 50% (i.e., d4/d=0.5). In some embodiments, to prevent damage to the lower structure during the forming of the third thin film, plasma may be supplied in the form of a pulse as shown in FIG. 12.

The fourth operation is repeated several times (y times) to form the passivation layer.

Fifth operation: The gap may be filled by repeating the third and fourth operations. The third and fourth operations may be repeated in a group cycle at a constant repetition rate. For example, a repetition rate of the third and fourth operations (x times: y times) may be repeated several times (z times) at a ratio of 1:5 or 1:10 or 1:20 etc., and the gap may be filled in a bottom-up method.

In some embodiments, amplitude of power supplied in the first and second operations in which the first thin film and the second thin film directly contacting the gap structure are formed may be less than amplitude of power supplied in the third and fourth operations. This is to reduce the effect of radicals on the lower structure. In more detail, as illustrated in FIG. 11, amplitude W1 of plasma powers in plasma pulse periods of the first and second operations may be less than amplitude W2 of plasma powers in the third and fourth operations. For example, amplitude of plasma powers in the first and second operations may be 200 W, and amplitude of plasma powers in the third and fourth operations may be 600 W.

Table 1 below shows an example of experimental conditions in which the above-described embodiment of FIG. 11 is performed.

| Items | Conditions |
|---|---|
| Process temperature (° C.) | Room temperature to 150° C. |
| | (preferably 50° C. to 150° C.) |
| Process pressure (Torr) | 1.0 Torr to 5.0 Torr (preferably 2.0 Torr |
| | to 3.0 Torr) |
| Si precursor | DIPAS (diisopropylaminosilane) |
| Reactant | Oxygen-containing gas, for example O₂, |
| | N₂O, CO₂, or a mixture thereof |
| Purge gas | Ar |
| Thin-film formation | N2, NH3 |
| inhibitor gas | |

First operation (first thin-film forming operation)

| | | |
|---|---|---|
| Process | Source supply (S1) | 0.05 sec to 2.0 sec (preferably 0.1 sec to |
| time | | 1.0 sec) |
| (sec) | Source purge (S2) | 0.05 sec to 2.0 sec (preferably 0.1 sec to |
| | | 1.0 sec) |
| | Plasma application | 0.05 sec to 2.0 sec (preferably 0.1 sec to |
| | (S3) | 1.0 sec) |
| | Purge (S4) | 0.05 sec to 2.0 sec (preferably 0.1 sec to |
| | | 1.0 sec) |
| | Repeat S1 cycle to | 50 cycles to 200 cycles (preferably 70 |
| | S4 cycle | cycles to 110 cycles) |
| Gas flow | Source carrier (Ar) | 100 sccm to 10,000 sccm (preferably |
| rate | | 600 sccm to 1,200 sccm) |
| (sccm) | Purge gas (Ar) | 1,000 sccm to 10,000 sccm (preferably |
| | | 3,000 sccm to 6,000 sccm) |
| Plasma | RF power (W) | 100 W to 400 W (preferably 100 W to |
| conditions | | 200 W) |
| | RF frequency | 13 MHz to 27 MHz |
| | (MHz) | |
| | Pulse duty ratio (%) | 30% to 70% (preferably 40% to 60%) |

Second operation (converting first thin film to second thin film)

| | | |
|---|---|---|
| Process | Source supply (S5) | 0.05 sec to 2.0 sec (preferably 0.1 sec to |
| time | | 1.0 sec) |
| (sec) | Source purge (S6) | 0.05 sec to 2.0 sec (preferably 0.1 sec to |
| | | 1.0 sec) |
| | Plasma application | 0.05 sec to 2.0 sec (preferably 0.1 sec to |
| | (S7) | 1.0 sec) |
| | Purge (S8) | 0.05 sec to 2.0 sec (preferably 0.1 sec to |
| | | 1.0 sec) |
| | S5 cycle to S8 cycle | 1 cycle to 50 cycles (preferably 10 cycle |
| | | to 20 cycles) |
| Gas flow | Source carrier (Ar) | 100 sccm to 10,000 sccm (preferably |
| rate | | 600 sccm to 1,200 sccm) |
| (sccm) | Reactant (N₂O) | 50 sccm to 1000 sccm (preferably 200 |
| | | sccm to 600 sccm) |
| | Purge (Ar) | 1,000 sccm to 10,000 sccm (preferably |
| | | 3,000 sccm to 6,000 sccm) |
| Plasma | RF power (W) | 100 W to 400 W (preferably 100 W to |
| conditions | | 200 W) |
| | RF frequency | 13 MHz to 27 MHz |
| | (MHz) | |
| | Pulse duty ratio (%) | 30% to 70% (preferably 40% to 60%) |

Third operation (forming passivation layer on second thin film)

| | | |
|---|---|---|
| Thin-film | Reactant purge (S9) | 0.05 sec to 10.0 sec (preferably 1.0 sec |
| formation | | to 5.0 sec) |
| inhibitor | Plasma application | 0.5 sec to 10.0 sec (preferably 1.0 sec to |
| gas | (S10) | 5.0 sec) |
| process | Purge (S11) | 0.05 sec to 5.0 sec (preferably 0.1 sec to |
| time (sec) | | 1.0 sec) |
| | S9 cycle to | 1 cycle |
| | S11 cycle | |
| Deposition | Source supply (S12) | 0.05 sec to 2.0 sec (preferably 0.1 sec to |
| process | | 1.0 sec) |
| time | Source purge (S13) | 0.05 sec to 2.0 sec (preferably 0.1 sec to |
| (sec) | | 1.0 sec) |
| | Plasma application | 0.05 sec to 2.0 sec (preferably 0.1 sec to |
| | (S14) | 1.0 sec) |
| | Purge (S15) | 0.05 sec to 2.0 sec (preferably 0.1 sec to |
| | | 1.0 sec) |
| | S12 cycle to S15 | 1 cycle to 10 cycles (preferably 1 cycle |
| | cycle | to 5 cycles) |
| Gas flow | Source carrier (Ar) | 100 sccm to 10,000 sccm (preferably |
| rate | | 600 sccm to 1,200 sccm) |
| (sccm) | Reactant (N2O) | 50 sccm to 1,000 sccm (preferably 200 |
| | | sccm to 600 sccm) |
| | Purge (Ar) | 1,000 sccm to 10,000 sccm (preferably |
| | | 3,000 sccm to 6,000 sccm) |
| | Thin-film formation | 500 sccm to 5,000 sccm (preferably |
| | inhibitor gas (N2) | 1,000 sccm to 2,000 sccm) |
| Plasma | RF power (W) | 400 W to 1,000 W (preferably 400 W |
| conditions | | to 600 W) |
| | RF frequency | 60 MHz to 100 MHz (preferably 60 |
| | (MHz) | MHz) |
| | Pulse duty ratio (%) | 30% to 70% (preferably 40% to 60%) |

Fourth operation (gap filling)

| | | |
|---|---|---|
| Deposition | Source supply (S12) | 0.05 sec to 2.0 sec (preferably 0.1 sec |
| process | | to 1.0 sec) |
| time | Source purge (S13) | 0.05 sec to 2.0 sec (preferably 0.1 sec |
| (sec) | | to 1.0 sec) |
| | Plasma application | 0.05 sec to 2.0 sec (preferably 0.1 sec |
| | (S14) | to 1.0 sec) |
| | Purge (S15) | 0.05 sec to 2.0 sec (preferably 0.1 sec |
| | | to 1.0 sec) |
| | S12 cycle to | 1 cycle to 10 cycles (preferably 1 cycle |
| | S15 cycle | to 5 cycles) |
| Gas flow | Source carrier (Ar) | 100 sccm to 10,000 sccm (preferably |
| rate | | 600 sccm to 1,200 sccm) |
| (sccm) | Reactant (N2O) | 50 sccm to 1,000 sccm (preferably 200 |
| | | sccm to 600 sccm) |
| | Purge (Ar) | 1,000 sccm to 10,000 sccm (preferably |
| | | 3,000 sccm to 6,000 sccm) |
| Plasma | RF power (W) | 400 W to 1,000 W (preferably 400 W |
| conditions | | to 600 W) |
| | RF frequency | 27 MHz |
| | (MHz) | |
| | Pulse duty ratio (%) | 30% to 70% (preferably 40% to 60%) |

In Table 1, a DIPAS precursor is used as the first reaction gas. However, the first reaction gas is not limited thereto. For example, as the first reaction gas, at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; TEOS, Si(OEt)₄; SiCl₄; HCD, Si₂Cl₆; 3DMAS, SiH(N(Me)₂)₃; BEMAS, Si H₂[N(Et)(Me)]₂; AHEAD, Si₂(NHEt)₆; TEAS, Si(NHEt)₄; Si₃H₈; DCS, SiH₂Cl₂; SiHI₃; SiH₂I₂, or a derivative and a group thereof, or a mixture thereof may be used. In addition, in Table 1, a N₂O gas is used as the third reaction gas. However, the third reaction gas is not limited thereto. For example, as the third reaction gas, at least one of O₂, O₃, CO₂, H₂O, NO₂, N₂O, or a mixture thereof may be used.

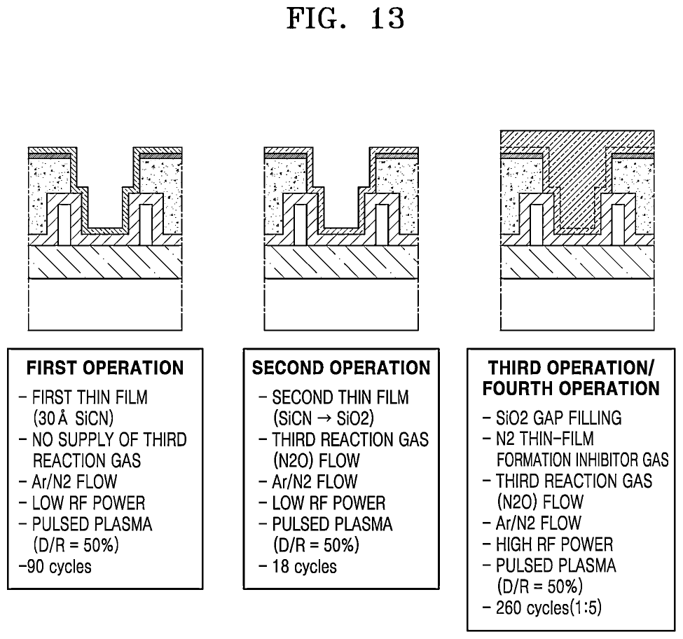

FIG. 13 is a view illustrating a substrate processing method according to embodiments. The substrate processing method according to the embodiments may be a variation of the substrate processing method according to the above-described embodiments. Hereinafter, repeated descriptions of the embodiments will not be given herein.

FIG. 13 schematically shows another embodiment according to the disclosure including a gap filling process through a first operation, a second operation, a third operation, and a fourth operation. The gap filling process of FIG. 13 is the same as the gap filling process of FIG. 11 except that a nitrogen gas is supplied together with an Ar gas in the first, second, and fourth operations. The nitrogen gas has high ionization energy, making plasma generation difficult. Therefore, by adding the nitrogen gas as a plasma suppression gas in the first, second and fourth operations to suppress plasma generation, damage to a lower film due to radicals during forming of a first thin film, a second thin film, and a third thin film may be further reduced.

In FIG. 13, the first operation is repeated 90 times (i.e., m=60), the second operation is repeated 18 times (i.e., n=18), and a group cycle consisting of the third and fourth operations in a 1:5 cycle ratio is repeated 260 times (i.e., z=260).

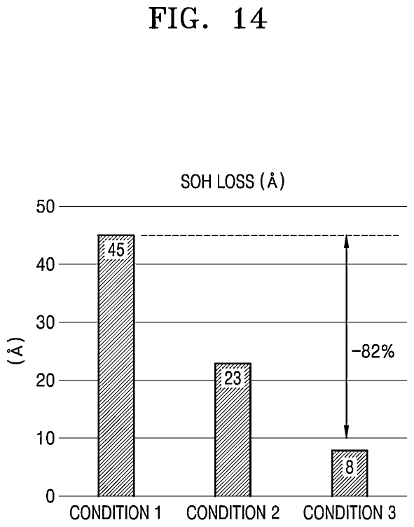

FIG. 14 is a view illustrating a degree of loss of a lower SOH mask layer when performing a gap filling process under different conditions. The lower SOH mask layer may be the SOH mask layer 6 in FIG. 4.

Conditions in FIG. 14 are as follows.

Condition 1: Filling a gap without executing the first operation 1001 (in FIG. 10) and the second operation 1002 (in FIG. 10)

Condition 2: The first operation 1001 (in FIG. 10) and the second operation 1002 (in FIG. 10) are performed to fill the gap, but no nitrogen gas as a plasma suppression gas is supplied during the first and second operations (the methods described in connection with FIGS. 10 and 11).

Condition 3: The first operation 1001 (in FIG. 10) and the second operation 1002 (in FIG. 10) are performed to fill the gap, and a nitrogen gas as a plasma suppression gas is supplied during the first and second operations (the methods described in connection with FIG. 13).

Referring to FIG. 14, when filling a gap without forming a second thin film on the gap by the first and second operations according to the disclosure (Condition 1), that is, when using the conventional gap filling method as described with reference to FIGS. 1 to 3, it can be seen that loss of a lower film (the mask layer 6 of FIG. 4) is 45 Å.

However, when the gap is filled after the second thin film is formed on the gap by the first and second operations according to the disclosure (Condition 2), it can be seen that the loss of the lower film is 23 Å, which is reduced by about 50% from Condition 1. From this, it can be seen that the second thin film formed by the first and second operations according to the disclosure may serve as a protective film for the lower film.

In addition, when a nitrogen gas is supplied as a plasma suppression gas during the first and second operations in addition to Condition 2, it can be seen that the loss of the lower film is 8 Å, which is 82% less than in Condition 1. From this, it can be seen that, by further supplying the nitrogen gas, the plasma generation is suppressed, thereby further reducing damage to the lower film due to radicals during a thin-film formation.

Therefore, the nitrogen gas may be additionally supplied during first thin film and second thin film forming operations performed in the above-described embodiments, so that a gap filling process may be performed while minimizing damage to the lower film (especially, a sidewall of the mask layer 6 in FIG. 4).

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing method comprising:
providing a substrate comprising a structure comprising a gap;
forming a first thin film on the structure by performing a first cycle a plurality of times, wherein the first cycle comprises:
supplying a first reaction gas onto the structure,
supplying a second reaction gas, wherein the second reaction gas has no chemical reactivity with the first reaction gas,
stopping supplying the first reaction gas,
after stopping the first reaction gas, applying a plasma, wherein the plasma is formed from a gas comprising the second reaction gas, and
a step of purging;
after performing the first cycle a plurality of times, performing a second cycle a plurality of times to form a second thin film by changing a chemical composition of the first thin film, wherein the second cycle comprises:
supplying a third reaction gas onto the substrate, and
a step of purging.

2. The substrate processing method of claim 1, wherein the plasma is formed from a gas consisting essentially of the second reaction gas.

3. The substrate processing method of claim 1, further comprising:
after performing the second cycle a plurality of times, performing a super cycle a plurality of times, wherein the super cycle comprises performing a third cycle a plurality of times to form a passivation layer followed by the fourth cycle a plurality of times,
wherein the third cycle comprises supplying a thin-film formation inhibitor gas comprising nitrogen.

4. The substrate processing method of claim 3, wherein there are no intervening steps between performing the second cycle a plurality of times and performing the super cycle a plurality of times.

5. The substrate processing method of claim 1, wherein the third reaction gas comprises at least one of O₂, O₃, CO₂, H₂O, NO₂, N₂O, or a mixture thereof.

6. The substrate processing method of claim 1, wherein the second cycle comprises consists essentially of a step of supplying a third reaction gas onto the substrate and a step of purging.

7. The substrate processing method of claim 1, wherein, after performing the second cycle a plurality of times, performing a fourth cycle a plurality of times to form a third thin film having a same component as that of the second thin film on the second thin film while filling the gap.

8. The substrate processing method of claim 3, wherein the thin-film formation inhibitor gas is supplied under a pulsed high-frequency power condition.

9. The substrate processing method of claim 8, wherein the passivation layer is formed on a second thin film in an upper portion of the gap, wherein the passivation layer inhibits the forming of the third thin film on the second thin film in the upper portion of the gap by removing bonding sites on the second thin film that bind to the first reaction gas, wherein low-frequency power is supplied during the forming of the third thin film.

10. The substrate processing method of claim 1, wherein the second reaction gas consists essentially of an inert gas.

11. The substrate processing method of claim 1, wherein the first reaction gas comprises an aminosilane-based silicon-containing source gas comprising a methyl group or an ethyl group.

12. The substrate processing method of claim 1, wherein the first cycle consists essentially of the step of supplying the first reaction gas onto the structure, a step of supplying a second reaction gas onto the structure, a step of applying a plasma, and the step of purging the residue.

13. The substrate processing method of claim 1, wherein the step of forming the third film continues until the third film fills the gap, wherein during the filling of the gap, a width of an inlet at the upper portion of the gap is maintained to be greater than a lower width of the gap, wherein the gap is filled without voids or seams being generated in the gap.

14. The substrate processing method of claim 1, wherein gases supplied during the first cycle consist essentially of the first reaction gas and the second reaction gas.

15. The substrate processing method of claim 1, wherein the first thin film is thermally and chemically adsorbed on the structure and then the second reaction gas is activated by plasma, thereby decomposing and densifying the thermally and chemically adsorbed first thin film by the activated second reaction gas.

16. The substrate processing method of claim 7, wherein forming the third thin film comprises supplying the first reaction gas and the third reaction gas.

17. A substrate processing method comprising:
providing a substrate in a reaction chamber;
forming a first thin film on the substrate, wherein forming the first thin film comprises:
supplying a first reaction gas,
supplying a second reaction gas comprising an inert gas, and
applying an inert gas plasma;
after forming the first thin film, changing the chemical composition of the first thin film, wherein changing the chemical composition of the first thin film comprises:
supplying a third reaction gas comprising oxygen;
after changing the chemical composition of the first thin film, forming a second thin film on the first thin film.

18. The substrate processing method of claim 17, wherein the first reaction gas comprises an aminosilane-based silicon-containing source gas comprising a methyl group or an ethyl group.

19. A substrate processing method comprising:
providing a substrate in a reaction chamber;
forming a first thin film on the substrate, wherein forming the first thin film comprises:
supplying a first reaction gas,
supplying a second reaction gas comprising an inert gas, and
applying an inert gas plasma;
after forming the first thin film, changing the chemical composition of the first thin film, wherein changing the chemical composition of the first thin film comprises:
supplying a third reaction gas comprising oxygen;
after changing the chemical composition of the first thin film, forming a passivation layer on the first thin film, wherein forming a passivation layer comprises a thin film formation inhibitor gas.

20. The substrate processing method of claim 19, further comprising:
after forming the passivation layer, forming a second thin film, wherein the second thin film comprises a same component as the first thin film.
